(19) United States
(12) Patent Application Publication
(10) Pub. No.: US 2026/0040558 A1
(43) Pub. Date: Feb. 5, 2026

(54) MICROELECTRONIC DEVICES, MEMORY DEVICES, AND ASSOCIATED SYSTEMS AND METHODS

(71) Applicant: Micron Technology, Inc., Boise, ID (US)

(72) Inventors: Anna Maria Conti, Milano (IT); Qui V. Nguyen, San Jose, CA (US); Mun Pyo Hong, Pleasanton, CA (US)

(21) Appl. No.: 19/254,982

(22) Filed: Jun. 30, 2025

Related U.S. Application Data
(60) Provisional application No. 63/677,808, filed on Jul. 31, 2024.

(51) Int. Cl. H10B 43/30; H10B 41/10; H10B 41/30; H10B 43/10

(52) U.S. Cl. CPC H10B 43/30; H10B 41/10; H10B 41/30; H10B 43/10

(57) ABSTRACT

The microelectronic device includes blocks. Each block includes a vertically alternating sequence of conductive structures and insulative structures arranged in tiers. The microelectronic device further includes an array of block select (BS) devices vertically offset from the blocks. The array includes a first row of BS devices comprising double-gated BS devices, the double-gated BS devices respectively having two transistors sharing a source region. The array further includes a second row of BS devices comprising single-gated BS devices respectively having only one transistor. The array also includes a global word line structure coupled to a first source region of one of the double-gated BS devices of the first row of BS devices and a second source region of one of the single-gated BS devices of the second row of BS devices.

### CROSS-REFERENCE TO RELATED APPLICATION

This application claims the benefit under 35 U.S.C. § 119 (e) of U.S. Provisional Patent Application Ser. No. 63/677,808, filed Jul. 31, 2024, the disclosure of which is hereby incorporated herein in its entirety by this reference.

### TECHNICAL FIELD

Embodiments of the present disclosure generally relate to microelectronic devices. In particular, embodiments of the present disclosure relate to microelectronic devices, memory devices, and associated systems and methods.

### BACKGROUND

A continuing goal of the microelectronics industry has been to increase the memory density (e.g., the number of memory cells per memory die) of memory devices, such as non-volatile memory devices (e.g., NAND Flash memory devices). One way of increasing memory density in non-volatile memory devices is to utilize vertical memory array (also referred to as a “three-dimensional (3D) memory array”) architectures. A conventional vertical memory array includes vertical memory strings extending through openings in tiers of conductive structures (e.g., word line plates) and dielectric materials at each junction of the vertical memory strings and the conductive structures. Such a configuration permits a greater number of switching devices (e.g., transistors) to be located in a unit of die area (i.e., length and width of active surface consumed) by building the array upwards (e.g., longitudinally, vertically) on a die, as compared to structures with conventional planar (e.g., two-dimensional) arrangements of transistors.

Conventional 3D memory arrays include electrical connections between the conductive structures of the tiers and control logic devices (e.g., string drivers, word line drivers, access line drivers) within a base structure so that memory cells in the 3D memory array can be uniquely selected for writing, reading, or erasing operations. One method of forming such an electrical connection includes forming at least one so-called “staircase” (or “stair step”) structure at edges (e.g., horizontal ends) of the tiers. The staircase structure includes individual “steps” defining contact regions of the conductive structures. An assembly of the control logic devices may be provided in electrical communication with the steps of the staircase structure and, hence, the conductive structures and the memory cells of the 3D memory array, by way of routing and interconnect structures.

### BRIEF DESCRIPTION OF THE DRAWINGS

FIG. 1 illustrates a simplified top-down view of a microelectronic device in accordance with embodiments of the disclosure;

FIG. 2 illustrates an enlarged view of a portion of the microelectronic device of FIG. 1;

FIG. 3 illustrates a simplified top-down view of the microelectronic device of FIGS. 1 and 2 including block select routing paths, in accordance with embodiments of the disclosure;

FIG. 4 illustrates a simplified top-down view of the microelectronic device of FIGS. 1-3;

FIG. 5 illustrates a simplified top-down view of a configuration for the microelectronic device of FIGS. 1-4;

FIGS. 6 and 7 illustrate simplified top-down views of configurations for microelectronic devices, in accordance with embodiments of the disclosure;

FIGS. 8-11 illustrate simplified top-down views showing components of a microelectronic device, in accordance with embodiments of the disclosure;

FIG. 12 illustrates a simplified, vertical cross-sectional view of a microelectronic device, in accordance with embodiments of the disclosure; and

FIG. 13 is a schematic block diagram of an electronic system, in accordance with embodiments of the disclosure.

### DETAILED DESCRIPTION

The following description provides specific details, such as material compositions, shapes, and sizes, in order to provide a thorough description of embodiments of the disclosure. However, a person of ordinary skill in the art would understand that the embodiments of the disclosure may be practiced without employing these specific details. Indeed, the embodiments of the disclosure may be practiced in conjunction with conventional microelectronic device fabrication techniques employed in the industry. In addition, the description provided below does not form a complete process flow for manufacturing a microelectronic device (e.g., a memory device). The structures described below do not form a complete microelectronic device. Only those process acts and structures necessary to understand the embodiments of the disclosure are described in detail below. Additional acts to form a complete microelectronic device from the structures may be performed by conventional fabrication techniques.

Drawings presented herein are for illustrative purposes only and are not meant to be actual views of any particular material, component, structure, device, or system. Variations from the shapes depicted in the drawings as a result, for example, of manufacturing techniques and/or tolerances, are to be expected. Thus, embodiments described herein are not to be construed as being limited to the particular shapes or regions as illustrated, but include deviations in shapes that result, for example, from manufacturing. For example, a region illustrated or described as box-shaped may have rough and/or nonlinear features, and a region illustrated or described as round may include some rough and/or linear features. Moreover, sharp angles that are illustrated may be rounded, and vice versa. Thus, the regions illustrated in the figures are schematic in nature, and their shapes are not intended to illustrate the precise shape of a region and do not limit the scope of the present claims. The drawings are not necessarily to scale. Additionally, elements common between figures may retain the same numerical designation.

As used herein, a “memory device” means and includes microelectronic devices exhibiting memory functionality, but not necessarily limited to memory functionality. Stated another way, and by way of non-limiting example only, the term “memory device” includes not only conventional memory (e.g., conventional non-volatile memory; conventional volatile memory), but also includes an application specific integrated circuit (ASIC) (e.g., a system on a chip (SoC)), a microelectronic device combining logic and memory, and a graphics processing unit (GPU) incorporating memory.

As used herein, the terms “configured” and “configuration” refers to a size, a shape, a material composition, a material distribution, orientation, and arrangement of at least one feature (e.g., one or more of at least one structure, at least one material, at least one region, at least one device) facilitating use of the at least one feature in a pre-determined way.

As used herein, the phrase “coupled to” refers to structures operatively connected with each other, such as electrically connected through a direct Ohmic connection or through an indirect connection (e.g., by way of another structure).

As used herein, the term “substantially” in reference to a given parameter means and includes to a degree that one skilled in the art would understand that the given parameter, property, or condition is met with a small degree of variance, such as within acceptable manufacturing tolerances. By way of example, depending on the particular parameter, property, or condition that is substantially met, the parameter, property, or condition may be at least 90.0 percent met, at least 95.0 percent met, at least 99.0 percent met, at least 99.9 percent met, or even 100.0 percent met.

As used herein, “about” or “approximately” in reference to a numerical value for a particular parameter is inclusive of the numerical value and a degree of variance from the numerical value that one of ordinary skill in the art would understand is within acceptable tolerances for the particular parameter. For example, “about” or “approximately” in reference to a numerical value may include additional numerical values within a range of from 90.0 percent to 110.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

As used herein, relational terms, such as “beneath,” “below,” “lower,” “bottom,” “above,” “upper,” “top,” “front,” “rear,” “left,” “right,” and the like, may be used for case of description to describe one element's or feature's relationship to another element(s) or feature(s) as illustrated in the drawings. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Thus, the term “below” can encompass both an orientation of above and below, depending on the context in which the term is used, which will be evident to one of ordinary skill in the art. The materials may be otherwise oriented (e.g., rotated 90 degrees, inverted, flipped) and the spatially relative descriptors used herein interpreted accordingly.

As used herein, the singular forms “a,” “an,” and “the” are intended to include the plural forms as well, unless the context clearly indicates otherwise.

As used herein, the term “and/or” means and includes any and all combinations of one or more of the associated listed items.

As used herein, the terms “vertical,” “longitudinal,” “horizontal,” and “lateral” are in reference to a major plane of a structure and are not necessarily defined by earth's gravitational field. A “horizontal,” “longitudinal,” or “lateral” direction is a direction that is substantially parallel to the major plane of the structure, while a “vertical” direction is a direction that is substantially perpendicular to the major plane of the structure. The major plane of the structure is defined by a surface of the structure having a relatively large area compared to other surfaces of the structure. With reference to the drawings, a “horizontal,” “longitudinal,” or “lateral” direction may be perpendicular to an indicated “Z” axis, and may be parallel to an indicated “X” axis and/or parallel to an indicated “Y” axis; and a “vertical” direction may be parallel to an indicated “Z” axis, may be perpendicular to an indicated “X” axis, and may be perpendicular to an indicated “Y” axis.

As used herein, features (e.g., materials, structures, regions, circuitry, devices) described as “neighboring” one another means and includes features of the disclosed identity (or identities) that are located most proximate (e.g., closest to) one another. Additional features (e.g., additional material, additional structures, additional regions, additional circuitry, additional devices) not matching the disclosed identity (or identities) of the “neighboring” features may be disposed between the “neighboring” features. Put another way, the “neighboring” features may be positioned directly adjacent one another, such that no other feature intervenes between the “neighboring” features; or the “neighboring” features may be positioned indirectly adjacent one another, such that at least one feature having an identity other than that associated with at least one the “neighboring” features is positioned between the “neighboring” features. Accordingly, features described as “vertically neighboring” one another means and includes features of the disclosed identity (or identities) that are located most vertically proximate (e.g., vertically closest to) one another. Moreover, features described as “horizontally neighboring” one another means and includes features of the disclosed identity (or identities).

As used herein, “conductive material” means and includes electrically conductive material such as one or more of a metal (e.g., tungsten (W), titanium (Ti), molybdenum (Mo), niobium (Nb), vanadium (V), hafnium (Hf), tantalum (Ta), chromium (Cr), zirconium (Zr), iron (Fc), ruthenium (Ru), osmium (Os), cobalt (Co), rhodium (Rh), iridium (Ir), nickel (Ni), palladium (Pd), platinum (Pt), copper (Cu), silver (Ag), gold (Au), aluminum (Al)), an alloy (e.g., a Co-based alloy, an Fe-based alloy, an Ni-based alloy, an Fe-and Ni-based alloy, a Co-and Ni-based alloy, an Fe-and Co-based alloy, a Co-and Ni-and Fe-based alloy, an Al-based alloy, a Cu-based alloy, a magnesium (Mg)-based alloy, a Ti-based alloy, a steel, a low-carbon steel, a stainless steel), a conductive metal-containing material (e.g., a conductive metal nitride, a conductive metal silicide, a conductive metal carbide, a conductive metal oxide), and a conductively-doped semiconductor material (e.g., conductively-doped polysilicon, conductively-doped germanium (Ge), conductively-doped silicon germanium (SiGe)). In addition, a “conductive structure” means and includes a structure formed of and including conductive material.

As used herein, “insulative material” means and includes electrically insulative material, such as one or more of at least one dielectric oxide material (e.g., one or more of a silicon oxide (SiOₓ), phosphosilicate glass, borosilicate glass, borophosphosilicate glass, fluorosilicate glass, an aluminum oxide (AlOₓ), a hafnium oxide (HfOₓ), a niobium oxide (NbOₓ), a titanium oxide (TiOₓ), a zirconium oxide (ZrOₓ), a tantalum oxide (TaOₓ), and a magnesium oxide (MgOₓ)), at least one dielectric nitride material (e.g., a silicon nitride (SiN_{y})), at least one dielectric oxynitride material (e.g., a silicon oxynitride (SiOₓN_{y})), at least one dielectric oxycarbide material (e.g., silicon oxycarbide (SiOₓC_{y})), at least one hydrogenated dielectric oxycarbide material (e.g., hydrogenated silicon oxycarbide (SiCₓO_{y}H_{z})), and at least one dielectric carboxynitride material (e.g., a silicon carboxynitride (SiOₓC_{z}N_{y})). Formulae including one or more of “x,” “y,” and “z” herein (e.g., SiOₓ, AlOₓ, HfOₓ, NbOₓ, TiOₓ, SiN_{y}, SiOₓN_{y}, SiOₓC_{y}, SiCₓO_{y}H_{z}, SiOₓC_{z}N_{y}) represent a material that contains an average ratio of “x” atoms of one element, “y” atoms of another element, and “z” atoms of an additional element (if any) for every one atom of another element (e.g., Si, Al, Hf, Nb, Ti). As the formulae are representative of relative atomic ratios and not strict chemical structure, an insulative material may comprise one or more stoichiometric compounds and/or one or more non-stoichiometric compounds, and values of “x,” “y,” and “z” (if any) may be integers or may be non-integers. As used herein, the term “non-stoichiometric compound” means and includes a chemical compound with an elemental composition that cannot be represented by a ratio of well-defined natural numbers and is in violation of the law of definite proportions. In addition, an “insulative structure” means and includes a structure formed of and including insulative material.

As used herein, the term “semiconductor material” refers to a material having an electrical conductivity between those of insulative materials and conductive materials. For example, a semiconductor material may have an electrical conductivity of between about 10⁻⁸ Siemens per centimeter (S/cm) and about 10⁴ S/cm (10⁶ S/m) at room temperature. Examples of semiconductor materials include elements found in column IV of the periodic table of elements such as silicon (Si), germanium (Ge), and carbon (C). Other examples of semiconductor materials include compound semiconductor materials such as binary compound semiconductor materials (e.g., gallium arsenide (GaAs)), ternary compound semiconductor materials (e.g., AlₓGa₁₋ₓAs), and quaternary compound semiconductor materials (e.g., GaₓIn₁₋ₓAsYP_{1-y}), without limitation. Compound semiconductor materials may include combinations of elements from columns III and V of the periodic table of elements (III-V semiconductor materials) or from columns II and VI of the periodic table of elements (II-VI semiconductor materials), without limitation. Further examples of semiconductor materials include oxide semiconductor materials such as zinc tin oxide (ZnₓSn_{y}O, commonly referred to as “ZTO”), indium zinc oxide (InₓZn_{y}O, commonly referred to as “IZO”), zinc oxide (ZnₓO), indium gallium zinc oxide (InₓGa_{y}Zn_{z}O, commonly referred to as “IGZO”), indium gallium silicon oxide (InₓGa_{y}Si_{z}O, commonly referred to as “IGSO”), indium tungsten oxide (InₓW_{y}O, commonly referred to as “IWO”), indium oxide (InₓO), tin oxide (SnₓO), titanium oxide (TiₓO), zinc oxide nitride (ZnₓON_{z}), magnesium zinc oxide (MgₓZn_{y}O), zirconium indium zinc oxide (ZrₓIn_{y}Zn_{z}O), hafnium indium zinc oxide (HfₓIn_{y}Zn_{z}O), tin indium zinc oxide (SnₓIn_{y}Zn_{z}O), aluminum tin indium zinc oxide (AlₓSn_{y}In_{z}Zn_{z}O), silicon indium zinc oxide (SiₓIn_{y}Zn_{z}O), aluminum zinc tin oxide (AlₓZn_{y}Sn_{z}O), gallium zinc tin oxide (GaₓZn_{y}Sn_{z}O), zirconium zinc tin oxide (ZrₓZn_{y}Sn_{z}O), and other similar materials. In addition, each of a “semiconductor structure” and a “semiconductive structure” means and includes a structure formed of and including semiconductor material.

Formulae including one or more of “x,” “y,” and “z” herein (e.g., SiOₓ, AlOₓ, HfOₓ, NbOₓ, TiOₓ, SiN_{y}, SiOₓ N_{y}, SiOₓC_{y}, SiCₓO_{y}H_{z}, SiOₓC_{z}N_{y}) represent a material that contains an average ratio of “x” atoms of one element, “y” atoms of another element, and “z” atoms of an additional element (if any) for every one atom of another element (e.g., Si, Al, Hf, Nb, Ti). As the formulae are representative of relative atomic ratios and not strict chemical structure, an insulative material may comprise one or more stoichiometric compounds and/or one or more non-stoichiometric compounds, and values of “x,” “y,” and “z” (if any) may be integers or may be non-integers. As used herein, the term “non-stoichiometric compound” means and includes a chemical compound with an elemental composition that cannot be represented by a ratio of well-defined natural numbers and is in violation of the law of definite proportions. In addition, an “insulative structure” means and includes a structure formed of and including insulative material.

As used herein, the term “homogeneous” means relative amounts of elements included in a feature (e.g., a material, a structure) do not vary throughout different portions (e.g., different horizontal portions, different vertical portions) of the feature. Conversely, as used herein, the term “heterogeneous” means relative amounts of elements included in a feature (e.g., a material, a structure) vary throughout different portions of the feature. If a feature is heterogeneous, amounts of one or more elements included in the feature may vary stepwise (e.g., change abruptly), or may vary continuously (e.g., change progressively, such as linearly, parabolically) throughout different portions of the feature. The feature may, for example, be formed of and include a stack of at least two different materials.

Unless the context indicates otherwise, the materials described herein may be formed by any suitable technique including, but not limited to, spin coating, blanket coating, chemical vapor deposition (CVD), plasma enhanced CVD (PECVD), atomic layer deposition (ALD), plasma enhanced ALD (PEALD), physical vapor deposition (PVD) (e.g., sputtering), or epitaxial growth. Depending on the specific material to be formed, the technique for depositing or growing the material may be selected by a person of ordinary skill in the art. In addition, unless the context indicates otherwise, removal of materials described herein may be accomplished by any suitable technique including, but not limited to, etching (e.g., dry etching, wet etching, vapor etching), ion milling, abrasive planarization (e.g., chemical-mechanical planarization (CMP)), or other known methods.

As used herein, the term “pitch” refers to a distance between identical points in two neighboring features.

As used herein, the term “NMOS” transistor means and includes a so-called metal-oxide transistor having a P-type channel region, an N-type channel region, or an I-type channel region. The gate of the NMOS transistor may comprise a conductive metal, another conductive material, such as polysilicon, or a combination thereof. As used herein, the term “PMOS” transistor means and includes a so-called metal-oxide transistor having a P-type channel region, an N-type channel region, or an I-type channel region. The gate of the PMOS transistor may comprise a conductive metal, another conductive material, such as polysilicon, or a combination thereof. Accordingly, the gate structures of such transistors may include conductive materials that are not necessarily metals.

As discussed above, vertical memory arrays facilitate a greater number of switching devices (e.g., transistors) to be located in a unit of die area (i.e., length and width of active surface consumed) by building the array upwards (e.g., longitudinally, vertically) on a dic, as compared to structures with conventional planar (e.g., two-dimensional) arrangements of transistors. As the number of memory cells in a 3D memory array has increased, electrically connecting the memory cells of the 3D memory array to the assembly of control logic devices within the base structure has created sizing and spacing complications associated with the increased quantities and dimensions of routing and interconnect structures required to facilitate the electrical connection. In addition, the quantities, dimensions, and arrangements of different control logic devices employed within the base structure can also undesirably impede reductions to the size of a 3D memory array, increases to the storage density of the 3D memory array, and/or reductions in fabrication costs. Further increasing the number of control logic devices in a unit of die area may be achieved by changing an arrangement of the control logic devices. Embodiments of the disclosure may facilitate greater numbers of control logic devices in a unit area, which may facilitate further increases in memory array density.

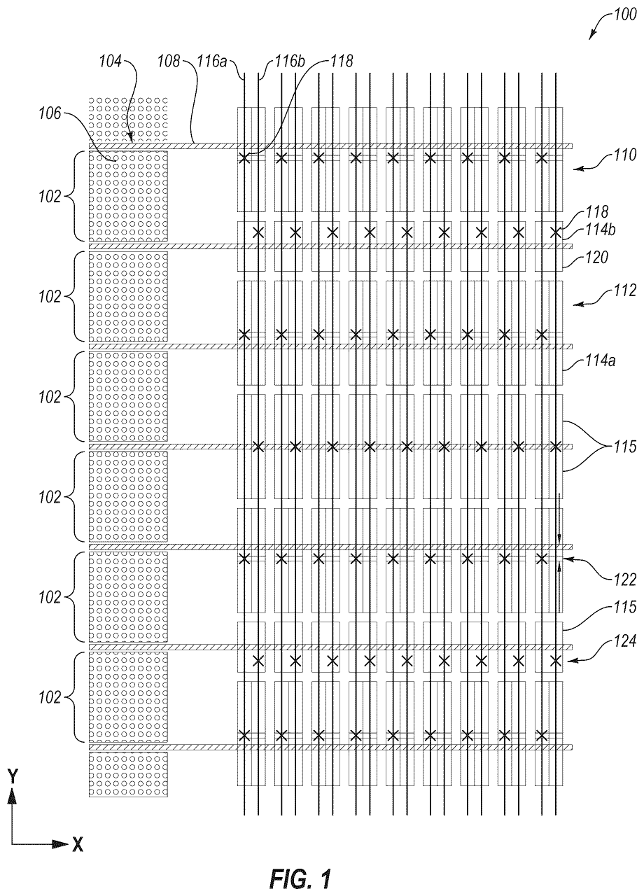

FIG. 1 illustrates a simplified, partial plan view of a microelectronic device 100, including overlapping structures from different vertical positions in the microelectronic device 100. The microelectronic device 100 is separated into multiple blocks 102. The blocks 102 each include multiple tiers respectively including conductive material vertically neighboring and insulative material. The blocks 102 are horizontally separated from one another by block separation regions 104, which may individually be a slot formed between horizontally neighboring (e.g., in the Y-direction) blocks 102 that is filled with isolation material (e.g., insulative material configured to substantially prevent electrical connections between the tiers in the neighboring blocks 102). In some embodiments, block contact structures 108, such as access line contact structures, support contact structures, and select gate contact structures, may extend through the microelectronic device 100 in the block separation region 104.

The blocks 102 may individually include a plurality (e.g., array) of cell pillar structures 106 within a horizontal area thereof. The cell pillar structures 106 may individually be formed of and include a stack of materials. By way of non-limiting example, each of the cell pillar structures 106 may be formed to include a charge-blocking material, such as first dielectric oxide material (e.g., SiOₓ, such as SiO₂; AlOₓ, such as Al₂O₃); a charge-trapping material, such as a dielectric nitride material (e.g., SiN_{y}, such as Si₃N₄); a tunnel dielectric material, such as a second dielectric oxide material (e.g., SiOₓ, such as SiO₂); a channel material, such as a semiconductor material (e.g., silicon, such as polycrystalline silicon); and a dielectric fill material (e.g., a dielectric oxide, a dielectric nitride, air). The charge-blocking material may be formed on or over surfaces of the conductive structures and the insulative structures of the tiers of the associated block 102 at least partially defining horizontal boundaries of the cell pillar structures 106; the charge-trapping material may be horizontally surrounded by the charge-blocking material; the tunnel dielectric material may be horizontally surrounded by the charge-trapping material; the channel material may be horizontally surrounded by the tunnel dielectric material; and the dielectric fill material may be horizontally surrounded by the channel material.

Intersections of the cell pillar structures 106 and the conductive material of some of the tiers (e.g., access line tiers) of a respective block 102 of the microelectronic device 100 form strings of memory cells vertically extending through the block 102. In some embodiments, the memory cells formed at the intersections of the conductive material of the active access line tiers and the cell pillar structures 106 comprise so-called “MONOS” (metal-oxide-nitride-oxide-semiconductor) memory cells. In additional embodiments, the memory cells comprise so-called “TANOS” (tantalum nitride-aluminum oxide-nitride-oxide-semiconductor) memory cells, or so-called “BETANOS” (band/barrier engineered TANOS) memory cells, each of which are subsets of MONOS memory cells. In further embodiments, the memory cells comprise so-called “floating gate” memory cells including floating gates (e.g., metallic floating gates) as charge storage structures.

The microelectronic device 100 includes a block select (BS) device array 110 formed of multiple BS devices, including double-gated BS devices 114a and single-gated BS devices 114b (collectively referred to herein as BS devices 114). The double-gated BS devices 114a may respectively include two (2) transistors 115 (e.g., string driver transistors). Each of the two transistors 115 have its own gate electrode (e.g., BS gate electrode), gate dielectric material, channel region, and drain region, but the two (2) transistors 115 may share a source region with one another. The single-gated BS devices 114b may respectively include only one (1) transistor 115 (e.g., string driver transistor) having a source region, a drain region, a channel region, a gate electrode (e.g., BS gate electrode), and gate dielectric material. The BS devices 114 may be employed for BS operations for the blocks 102 of the microelectronic device 100, as described in further detail below. The BS devices 114 of the BS device array 110 each include a global contact structure 118 and at least one local contact structure 120. For example, the double-gated BS devices 114a include a global contact structure 118 and two local contact structures 120 on opposing ends of the double-gated BS device 114a. The global contact structure 118 is coupled to the shared source region of the two transistors of the double-gated BS device 114a, and the local contact structures 120 are coupled to unshared drain regions of the two transistors of the double-gated BS device 114a.

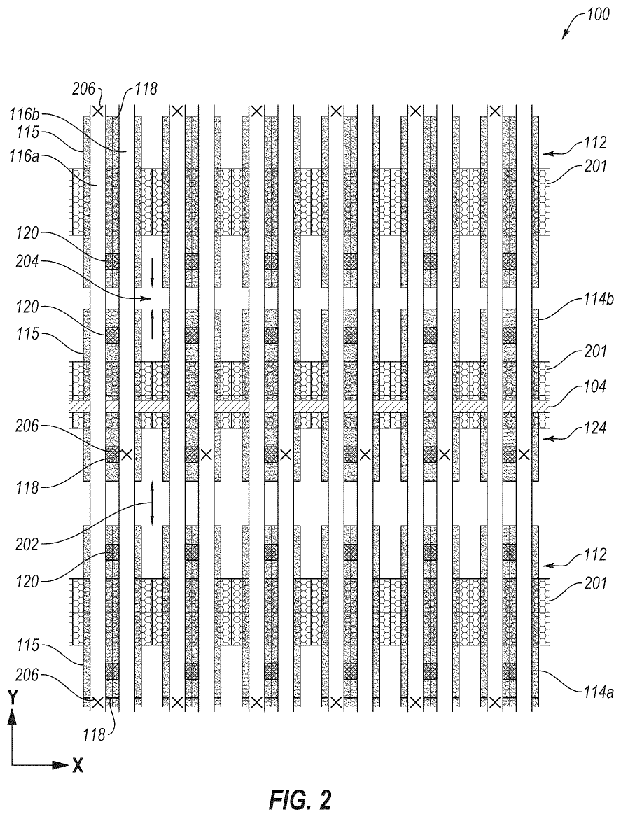

An individual double-gated BS device 114a may be configured and employed to direct a GWL signal received thereby by way of the global contact structure 118 to local word lines (e.g., local access lines) one of two of the blocks 102 operatively associated therewith based on selective activation (or deactivation) of one of the two (2) transistors 115 of the double-gated BS device 114a by way of one of two (2) BS gate electrodes 201 (FIG. 2) operatively associated with the double-gated BS device 114a. Put another way, the double-gated BS device 114a may be configured and operated to electrically connect (e.g., select, couple) and electrically disconnect (e.g., deselect, uncouple) local word lines (e.g., local access lines) of the associated blocks 102 to a global word line 116 coupled to the double-gated BS device 114a based on activation or deactivation of the transistors 115 thereof by way of BS signals directed to the BS gate electrodes of the double-gated BS device 114a. The double-gated BS devices 114a are respectively horizontally positioned such that the global contact structure 118 of the double-gated BS device 114a is positioned within or proximate a horizontal area of the block separation region 104 between two neighboring blocks 102. In addition, one of the local contact structures 120 of the double-gated BS device 114a is positioned within a horizontal area of a first block 102 of the two neighboring blocks 102, and another one of the local contact structures 120 of the local contact structures 120 is positioned within a horizontal area of a second block 102 of the two neighboring blocks 102. Thus, upon receiving a GWL signal at the global contact structure 118 and an activation signal from one of the BS gate electrodes thereof, the double-gated BS device 114a may direct the GWL signal to a local word line of one of the two neighboring blocks 102 by way of the local contact structure 120 coupled to the transistor 115 of the double-gated BS device 114a associated with the one of the BS gate electrodes. By coupling an individual double-gated BS device 114a to different local word lines of neighboring blocks 102, the double-gated BS device 114a may perform operations equivalent to two single-gated BS devices 114b while utilizing a relatively smaller space.

As illustrated in FIG. 1, two global word lines 116a, 116b horizontally overlap (e.g., in the X-direction) and extend over (e.g., in the Y-direction) each BS device 114 (e.g., each double-gated BS device 114a, each single-gated BS device 114b) the of the BS device array 110. The two global word lines 116a, 116b may facilitate separately activating transistors 115 of two horizontally neighboring (e.g., in the Y-direction) BS devices 114 that are connected to a same block 102 (by way of the local contact structure 120 operatively associated therewith) to substantially prevent redundant transistor 115 activation (and, hence, associated redundant GWL signal direction to local word lines of the block 102).

The double-gated BS devices 114a are arranged in rows 112 respectively horizontally extending in a direction (e.g., the X-direction) substantially parallel to the block separation regions 104 between the blocks 102. Size differences between the double-gated BS devices 114a and the blocks 102 may result in a horizontal offset 122 (e.g., in the Y-direction) between the global contact structures 118 and the block separation region 104 in some of the rows 112 of double-gated BS devices 114a. To maintain the arrangement discussed above, where the global contact structure 118 of the double-gated BS device 114a is horizontally positioned (e.g., in the Y-direction) at or proximate the block separation region 104 between two horizontally neighboring (e.g., in the Y-direction) blocks 102 and the local contact structures 120 of the double-gated BS device 114a are horizontally positioned (e.g., in the Y-direction) within horizontal areas of different blocks 102 of the two horizontally neighboring blocks 102, a gap row 124 may be used to adjust the horizontal position (e.g., in the Y-direction) of the rows 112 of double-gated BS devices 114a.

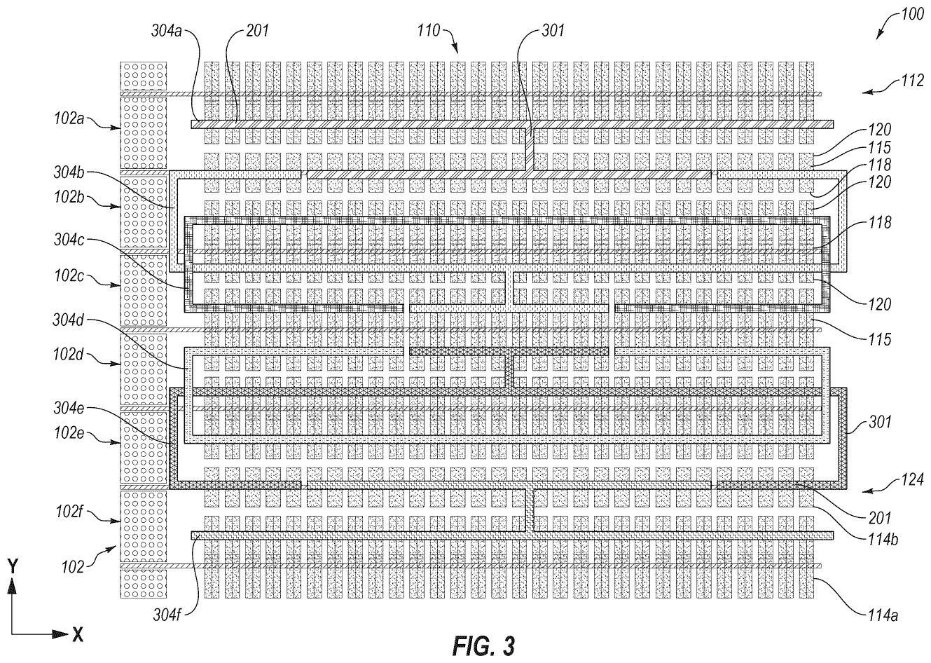

A row of single-gated BS devices 114b may be arranged in the gap row 124. As previously described herein, the single-gated BS devices 114b may respectively include only one (1) transistor 115 (e.g., string driver transistor) having a source region, a drain region, a channel region, a gate electrode (e.g., BS gate electrode), and gate dielectric material. The single-gated BS devices 114b respectively include a global contact structure 118 in contact with one of the source region and the drain region of the transistor 115 thereof, and a local contact structure 120 in contact with the other of the source region and the drain region of the transistor 115 thereof. The gap row 124 may horizontally overlap (e.g., in the Y-direction) the block separation region 104 between two horizontally neighboring (e.g., in the Y-direction) blocks 102, such that the single-gated BS devices 114b in the gap row 124 are positioned vertically (e.g., in the Z-direction) above or below the block separation region 104. The single-gated BS devices 114b may be oriented to position the local contact structure 120 over the block 102 with which the associated single-gated BS device 114b is associated. As discussed in further detail below with respect to FIG. 3, individual single-gated BS devices 114b in a gap row 124 may be associated with different blocks 102 of the two horizontally neighboring blocks 102 from other single-gated BS devices 114b in the same gap row 124.

The embodiment illustrated in FIG. 1 includes six blocks 102. The combination of double-gated BS devices 114a and single-gated BS devices 114b results in ten rows of transistors 115. Thus, for every three blocks 102 there are five rows of transistors 115. The additional rows of transistors 115 may facilitate increased memory density of the microelectronic device 100 as compared to conventional microelectronic devices.

FIG. 2 illustrates an enlarged view of a portion of the microelectronic device 100, including a gap row 124 between two rows 112 of double-gated BS devices 114a. As discussed above, the gap row 124 includes a row of single-gated BS devices 114b arranged therein. The single-gated BS devices 114b include global contact structures 118 and local contact structures 120. For an individual single-gated BS device 114b, the global contact structure 118 thereof is coupled to one of the two global word lines 116a, 116b horizontally overlapping (e.g., in the X-direction) and extending (e.g., in the Y-direction) over the single-gated BS device 114b. The global contact structures 118 of the single-gated BS devices 114b are coupled to a different global word line 116a, 116b than the double-gated BS devices 114a in the horizontally neighboring (e.g., in the Y-direction) rows 112, as indicated by the global word line connections 206. As illustrated in FIG. 2, the global contact structures 118 of the double-gated BS devices 114a in the two horizontally neighboring rows 112 are respectively coupled to a first global word line 116a, and the global contact structures 118 of the single-gated BS devices 114b in the gap row 124 are coupled to a second global word line 116b.

When the global word lines 116a, 116b are supplying signals (e.g., GWL signals) to associated BS devices 114, the voltage at the associated global contact structures 118 may be significantly greater than the operating voltage for the local contact structures 120. In the double-gated BS devices 114a, the global contact structures 118 are positioned in a central region (e.g., a central, shared source region) of the double-gated BS devices 114a, such that the global contact structures 118 of the double-gated BS devices 114a are distanced from the local contact structures 120 of any other BS devices 114 horizontally neighboring the double-gated BS devices 114a. In the single-gated BS devices 114b, the global contact structures 118 are positioned at or proximate on horizontal end (e.g., in the Y-direction) of the single-gated BS devices 114b, such that the global contact structures 118 of the double-gated BS devices 114a are relatively closer to local contact structures 120 of other BS devices 114 (e.g., double-gated BS devices 114a) horizontally neighboring (e.g., in the Y-direction) the single-gated BS devices 114b.

In some embodiments, the single-gated BS devices 114b in the gap row 124 are horizontally offset (e.g., in the Y-direction) within the gap row 124, such that a distance 202 between the global contact structure 118 of the single-gated BS device 114b and the local contact structure 120 of a horizontally neighboring double-gated BS device 114a is greater than a distance 204 between the local contact structure 120 of the single-gated BS device 114b and a local contact structure 120 of the double-gated BS device 114a horizontally neighboring (e.g., in the Y-direction) an opposite end of the single-gated BS device 114b. For example, the distance 202 between the global contact structure 118 of the single-gated BS device 114b and the local contact structure 120 of the horizontally neighboring double-gated BS device 114a may be within a range from about 7 μm to about 12 μm, such as within a range from about 8 μm to about 11 μm, or within a range from about 10 μm to about 11 μm. The distance 204 between the local contact structure 120 of the single-gated BS device 114b and a local contact structure 120 of a double-gated BS device 114a horizontally neighboring an opposite end of the single-gated BS device 114b from the global contact structure 118 may be within a range from about 3 μm to about 8 μm, such as within a range from about 4 μm to about 7 μm, or from about 5 μm to about 6 μm. Increasing the distance 202 between the global contact structure 118 of the single-gated BS device 114b and the local contact structure 120 of the horizontally neighboring double-gated BS device 114a may substantially prevent undesirable electrical shorts and/or undesirable cross-talk from occurring between the global contact structure 118 of the single-gated BS device 114b and the local contact structure 120 of the horizontally neighboring double-gated BS device 114a.

FIG. 3 illustrates a simplified plan view of the microelectronic device 100 including the blocks 102 and the BS device array 110. The microelectronic device 100 illustrated in FIG. 3, includes six blocks 102. As discussed above, the local contact structures 120 coupled to the transistors 115 of the BS devices 114 (double-gated BS devices 114a, single-gated BS devices 114b) in the BS device array 110 are coupled to respective local word lines of the blocks 102. To avoid redundant local contact structures 120, the BS devices 114 are respectively configured to selectively activate a single transistor 115 thereof during use and operation of the microelectronic device 100.

FIG. 3 illustrates BS gate routing paths 304 (e.g., a first BS gate routing path 304a, a second BS gate routing path 304b, a third BS gate routing path 304c, a 304d, a fifth BS gate routing path 304c, a sixth BS gate routing path 304f) associated with the blocks 102 (e.g., a first block 102a, a second block 102b, a third block 102c, a fourth block 102d, a fifth block 102e, a sixth block 102f). The BS gate electrodes 201 (FIG. 2) of different BS devices 114 (double-gated BS devices 114a, single-gated BS devices 114b) may form portions of the BS gate routing paths 304. In addition, BS gate routing 301 may couple the BS gate electrodes 201 of some of the BS devices 114 with the BS gate electrodes 201 of some others of the BS devices 114 horizontally offset (e.g., in the Y-direction) from the some of the BS devices 114. The BS gate routing path 304a, 304b, 304c, 304d, 304c, 304f indicate which transistors 115 (and, hence, which local contact structures 120) of the BS devices 114 are operatively associated with (e.g., coupled to) the local word lines of the different blocks 102a, 102b, 102c, 102d, 102e, 102f. As illustrated in FIG. 3, some of the blocks 102a, 102b, 102c, 102d, 102e, 102f may include connections to BS devices 114 in two (2) different rows 112/gap rows 124, while others of the blocks 102a, 102b, 102c, 102d, 102e, 102f may include connections to BS devices 114 in three (3) different rows 112/gap rows 124.

For example, as indicated by the first BS gate routing path 304a, the local word lines of first block 102a are connected to local contact structures 120 on one side of the double-gated BS devices 114a in the uppermost row 112 (e.g., in the Y-direction) and to the local contact structures 120 of a group of the single-gated BS devices 114b in the uppermost gap row 124. As indicated by second BS gate routing path 304b, the local word lines of second block 102b are connected to the local contact structures 120 in a second group of the single-gated BS devices 114b in the uppermost gap row 124, one set of the local contact structures 120 in the second row 112 of double-gated BS devices 114a from the top and a group of the local contact structures 120 in the third row of double-gated BS devices 114a from the top. As indicated by third BS gate routing path 304c, the local word lines of third block 102c are connected to the local contact structures 120 in a second set of the local contact structures 120 in the second row 112 of double-gated BS devices 114a from the top and a second group of the local contact structures 120 in the third row of double-gated BS devices 114a from the top. As indicated by fourth BS gate routing path 304d, the local word lines of fourth block 102d are connected to the local contact structures 120 in a group of the local contact structures 120 in the third row of double-gated BS devices 114a from the top, one set of the local contact structures 120 in the fourth row 112 of double-gated BS devices 114a from the top, and a group of the single-gated BS devices 114b in the lowermost gap row 124. As indicated by fifth BS gate routing path 304c, the local word lines of fifth block 102e are connected to the local contact structures 120 in a second group of the local contact structures 120 in the third row of double-gated BS devices 114a from the top and a second set of the local contact structures 120 in the fourth row 112 of double-gated BS devices 114a from the top. As indicated by sixth BS gate routing path 304f, the local word lines of sixth block 102f are connected to the local contact structures 120 in a second group of the local contact structures 120 in the lowermost gap row 124 of single-gated BS devices 114b and one set of the local contact structures 120 in the lowermost row 112 of double-gated BS devices 114a.

As illustrated in FIG. 3, none of the BS gate routing paths 304a, 304b, 304c, 304d, 304c, 304f horizontally (e.g., in the Y-direction) overlap themselves more than twice. The number of overlaps in the routing paths may match a number of global word lines 116a, 116b associated with each lateral column of the BS devices 114, such that each transistor 115 may be uniquely activated through a BS signal delivered through the BS gate routing path 304 operatively associated therewith. For example, in the embodiment of the microelectronic device 100 illustrated in FIG. 1, the microelectronic device 100 includes two global word lines 116a, 116b associated with each column of BS devices 114. In other embodiments, additional global word lines 116a, 116b may be used, such as three global word lines 116a, 116b or four global word lines 116a, 116b. In these embodiments, the BS gate routing paths 304a, 304b, 304c, 304d, 304c, 304f may horizontally overlap (e.g., in the Y-direction) more than two times, such as three times in embodiments having three global word lines 116a, 116b, or four times in embodiments having four global word lines 116a, 116b.

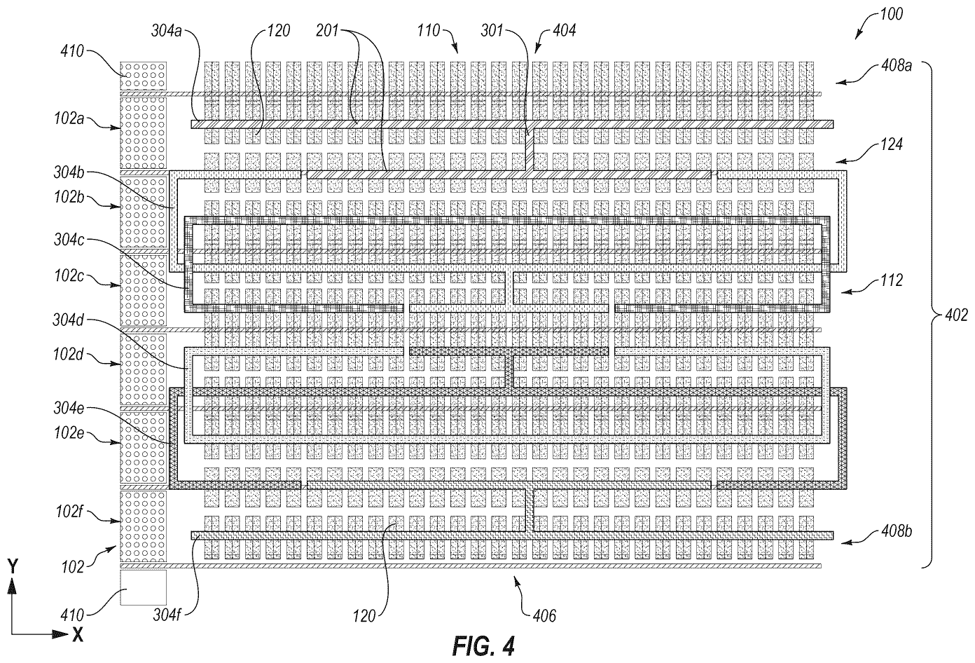

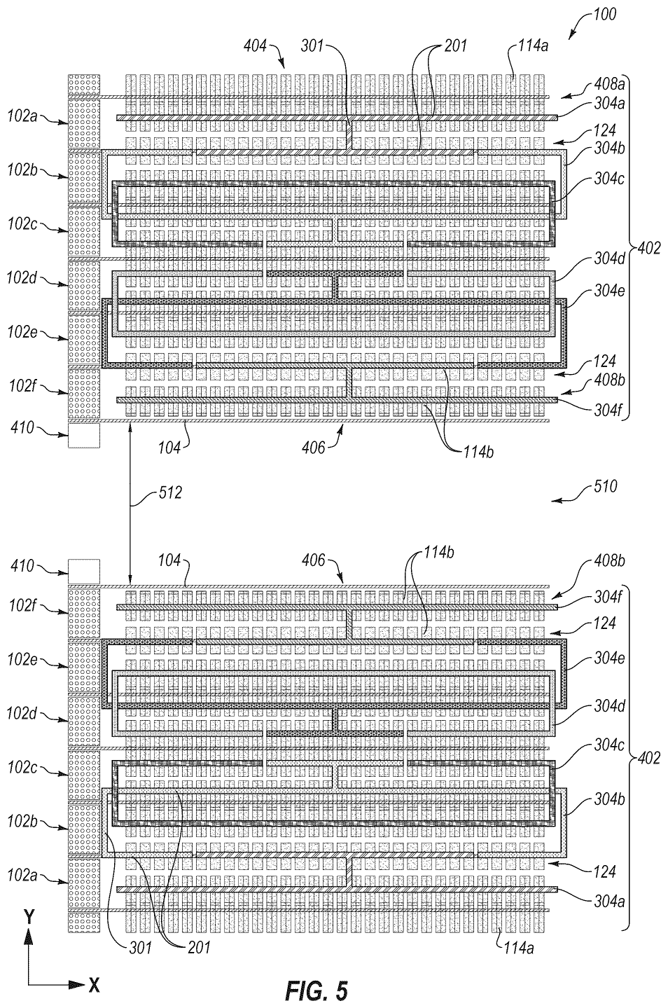

Referring now to FIG. 4, the blocks 102 may be arranged into a plane 402. In the embodiment illustrated in FIG. 4, the memory plane 402 includes six blocks 102a, 102b, 102c, 102d, 102e, 102f. Each of the blocks 102a, 102b, 102c, 102d, 102e, 102f are associated with several BS devices 114 in the BS device array 110 as illustrated by the BS gate routing paths 304a, 304b, 304c, 304d, 304c, 304f and described above, with respect to FIG. 3. The microelectronic device 100 may include multiple planes 402 positioned adjacent to one another, as further described and illustrated below with respect to FIGS. 5-7.

A first horizontal end 404 of the plane 402 is defined by a first row 408a of the blocks 102 and a second horizontal end 406 of the plane 402 is defined by a last row 408b of the blocks 102. The first horizontal end 404 and the second horizontal end 406 of the plane 402 may respectively include a placeholder block 410, that may (or may not) include cell pillar structures 106 similar to the blocks 102a, 102b, 102c, 102d, 102e, 102f. The placeholder blocks 410 may be substantially free of connections to any of the BS devices 114.

The local contact structures 120 of the BS devices 114, within horizontal areas of the first row 408a of blocks 102 and the last row 408b of blocks 102 may respectively be routed to the local word lines of one of the blocks 102. As discussed above, the BS gate routing paths 304a, 304b, 304c, 304d, 304c, 304f include the BS gate electrodes 201 of the associated transistors 115. The BS gate electrodes 201 in each of the BS gate routing paths 304a, 304b, 304c, 304d, 304c, 304f are configured to selectively activate the associated transistors 115 of the BS devices 114. When activated, an individual transistor 115 operatively connects the associated local contact structure 120 and global contact structure 118 of the associated transistor 115. Therefore, when activated, the BS gate electrodes 201 associated with each of the BS gate routing paths 304a, 304b, 304c, 304d, 304c, 304f, activate the transistors 115 along the associated BS gate routing paths 304a, 304b, 304c, 304d, 304c, 304f forming a connection between the local contact structures 120 in contact with the associated transistors 115, which are connected to the local word lines of the associated blocks 102a, 102b, 102c, 102d, 102e, 102f, and the global word lines connected to the global contact structures 118 in contact with the associated transistors 115. For example, in the embodiment illustrated in FIG. 4, the local contact structures 120 of the BS devices 114 within a horizontal area in the first row 408a of the blocks 102 are routed to the first block 102a, as illustrated by a first BS gate routing path 304a. The local contact structures 120 of the BS devices 114 in the last row 408b are routed to the sixth block 102f as illustrated by a sixth BS gate routing path 304f.

The BS devices 114 with a horizontal area of at least one of the first row 408a or the last row 408b of the blocks 102 may be single-gated BS devices 114b. For example, in the plane 402 illustrated in FIG. 4, a gap row 124 of the single-gated BS devices 114b is within or horizontally overlaps (e.g., in the Y-direction) the last row 408b of the blocks 102, such that no portion of the BS devices 114 horizontally overlapping the last row 408b extend into the horizontal span (e.g., in the Y-direction) of the placeholder block 410.

FIG. 5 illustrates a simplified, top-down view of a configuration for the microelectronic device 100 including an additional plane 402 horizontally offset (e.g., in the Y-direction) from the plane 402. As noted above, the microelectronic device 100 may include multiple planes 402. The planes 402 may have features and feature arrangements that mirror one another. For example, as illustrated in FIG. 5, the plane 402 includes the features previously described with reference to FIGS. 1 through 4 (e.g., six blocks 102a-102f, the associated BS devices 114, and the associated BS routing paths), and the additional plane 402 also includes such features, but in arrangement with is inverted in the Y-direction relative to that of the plane 402.

A plane separation region 510 may be defined between the planes 402 and the additional plane 402. The plane separation region 510 may be an area where additional contact structures and/or routing structures are present. The plane separation region 510 is substantially free of BS devices 114. The plane separation region 510 may define a distance 512 between the two planes 402. For example, the distance 512 between the two planes 402 may be within a range from about 180 μm to about 250 μm, such as within a range from about 200 μm to about 240 μm.

Keeping the BS devices 114 outside of horizontal spans extending into the placeholder blocks 410 of the horizontally neighboring planes 402 may facilitate reducing the distance 512 between the two planes 402 at least by permitting the plane separation region 510 to extend into the region defined by the opposing placeholder blocks 410. In the embodiment illustrated in FIG. 5, the last row 408b of the plane 402 and the opposing last row 408b of the additional plane 402 include single-gated BS devices 114b, such that no BS gate electrode 201 of a double-gated BS device 114a extends into the horizontal span (e.g., in the Y-direction) of the opposing placeholder blocks 410 of the two planes 402. Thus, the plane separation region 510 may extend into the horizontal span of the opposing placeholder blocks 410 to the block separation regions 104 defining the opposing lower ends 406 of the two planes 402.

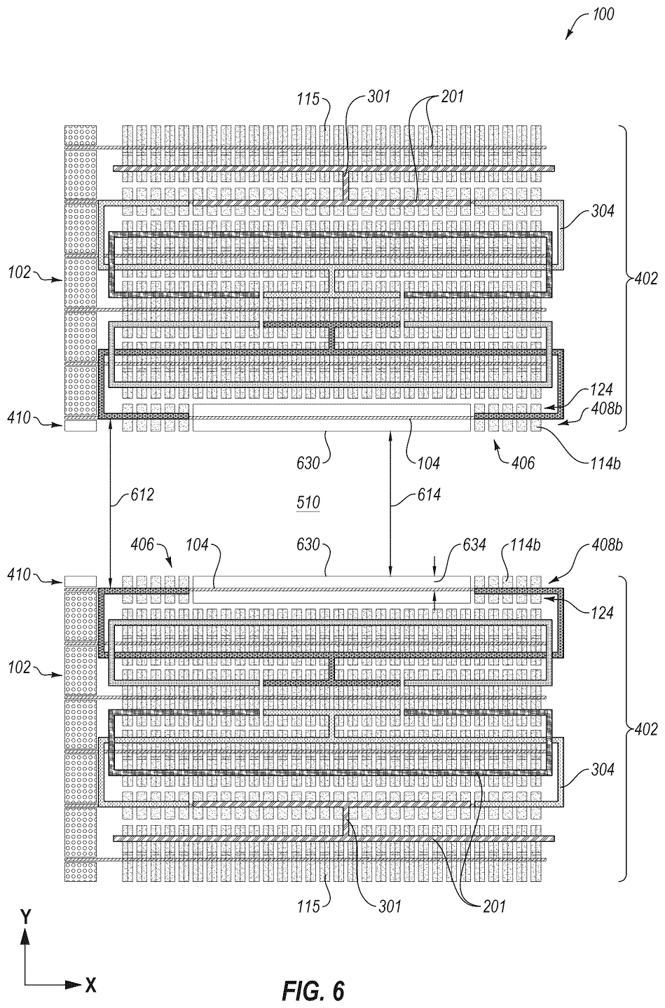

FIG. 6 illustrates a simplified top-down view of a configuration for the microelectronic device 100 including multiple planes 402. Each of the planes 402 includes multiple blocks 102 and BS devices 114a, 114b arranged in an array. The local contact structures in contact with the transistors 115 of the BS devices 114a, 114b are operatively associated with the blocks 102 as indicated by the BS gate routing paths 304 though the BS gate electrodes 201 of each of the BS gate routing paths.

In the embodiment illustrated in FIG. 6, each of the planes 402 includes five blocks 102. The BS gate routing paths 304 are substantially the same as the BS gate routing paths 304a, 304b, 304c, 304d, 304c, 304f described above with respect to FIGS. 3-5, but with the sixth BS gate routing path 304f (FIGS. 3-5) removed from the memory planes 402. The last rows 408b of the planes 402 proximate the plane separation region 510 are the gap rows 124 formed from the single-gated BS devices 114b. As illustrated in FIG. 6, the BS gate routing paths 304 do not extend over all the transistors 115 in the last rows 408b of the planes 402. Therefore, each of the last rows 408b of the planes 402 include unused transistors 630 (e.g., dummy transistors). In some embodiments, the region including the unused transistors 630 is free of transistors 115 (e.g., the unused transistors 630 are not included in the region).

In the embodiment illustrated in FIG. 6, the transistors 115 in the last rows 408b of the planes 402 extend beyond the block separation regions 104 that define the second horizontal ends 406 of the planes 402, such that the transistors 115 extend partially into the placeholder blocks 410. The transistors 115 may extend an overlap distance 634 into the placeholder blocks 410. The overlap distance 634 may be within a range of from about 10 μm to about 40 μm, such as from about 15 μm to about 25 μm.

The overlap distance 634 causes a distance 612 between the memory planes 402 to be greater than a distance 614 between the transistors 115 in the last rows 408b of the planes 402. The plane separation region 510 may define the distance 614 between the transistors 115 in the last rows 408b of the planes 402, such that the plane separation region 510 is free of transistors 115. Thus, the distance 612 between the planes 402 may be greater than the distance 614 by at least two times the overlap distance 634.

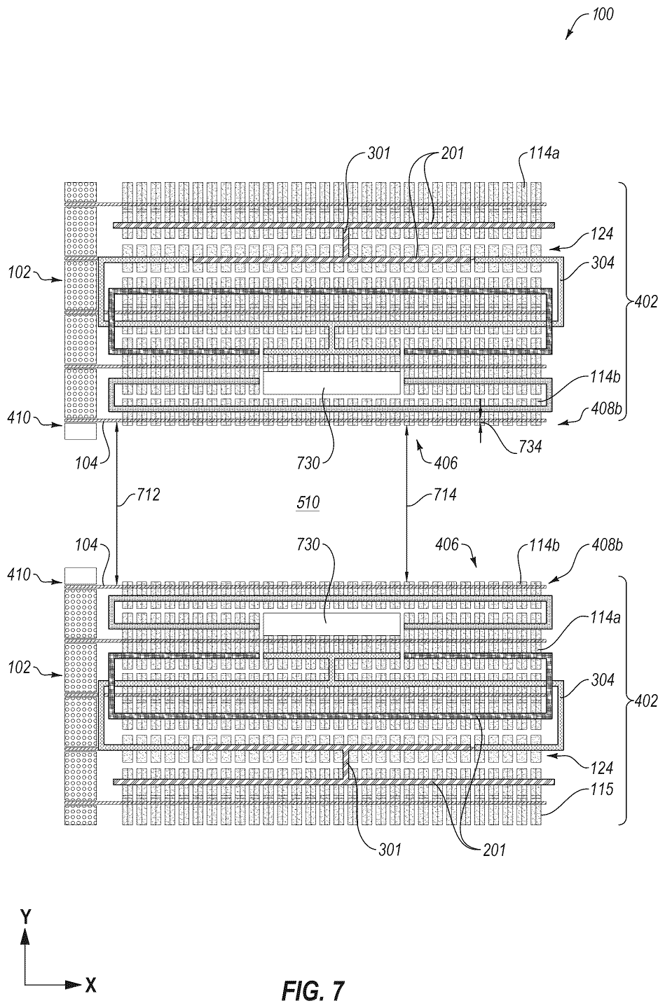

FIG. 7 illustrates a simplified top-down view of a configuration for the microelectronic device 100 including multiple planes 402. Each of the planes 402 include multiple blocks 102 and BS devices 114a, 114b arranged in an array. The local contact structures of the transistors 115 of the BS devices 114a, 114b are tied to the blocks 102 as indicated by the BS gate routing paths 304 though the BS gate electrodes 201 of each of the BS gate routing paths.

In the embodiment illustrated in FIG. 7, each of the planes 402 includes four blocks 102. The BS gate routing paths 304 are substantially the same as the BS gate routing paths 304a, 304b, 304c, 304d, 304c, 304f described above, with respect to FIGS. 3-5, but with the fifth BS gate routing path 304e (FIGS. 3-5) and the sixth BS gate routing path 304f (FIGS. 3-5) removed from each of the planes 402. The last rows 408b of the planes 402 include single-gated BS devices 114b. As illustrated in FIG. 7, the BS gate routing paths 304 extend over all the transistors 115 in the last rows 408b of the planes 402. The BS gate routing paths 304 also illustrate that a group of transistors 115 in the second to last rows of the planes 402 include unused transistors 730. In some embodiments, the region including the unused transistors 730 is free of transistors 115 (e.g., the unused transistors 730 are not included in the region).

In the embodiment illustrated in FIG. 7, the transistors 115 in the last rows 408b of the planes 402 extend beyond the block separation region 104 that define the second horizontal ends 406 of the planes 402, such that the transistors 115 extend partially into the placeholder blocks 410. The transistors 115 may extend an overlap distance 734 into the placeholder blocks 410. As discussed above, the transistors 115 in the last rows 408b are single-gated BS devices 114b rather than double-gated BS devices 114a. Arranging single-gated BS devices 114b in the last rows 408b of the planes 402 may substantially reduce the overlap distance 734. For example, the overlap distance 734 may be within a range of from about 5 μm to about 40 μm, such from about 10 μm to about 20 μm.

The overlap distance 734 causes a distance 712 between the planes 402 to be greater than a distance 714 between the transistors 115 in the last rows 408b of the planes 402. The plane separation region 510 may define the distance 712 between the transistors 115 in the last rows 408b of the planes 402, such that the plane separation region 510 is free of transistors 115. Thus, the distance 712 between the planes 402 may be greater than the distance 714 by at least two times (2X) the overlap distance 734.

In accordance with additional embodiments of the disclosure, memory density of a microelectronic device is increased by changing an orientation of the BS devices (and, hence, the transistors thereof) associated with the blocks in the microelectronic device. Changing the orientation of the BS devices may reduce the horizontal space (e.g., in the Y-direction) used by the BS devices, which may facilitate increasing the number of BS devices associated with each of the blocks. Such a changed orientation of the BS devices is described in further detail below.

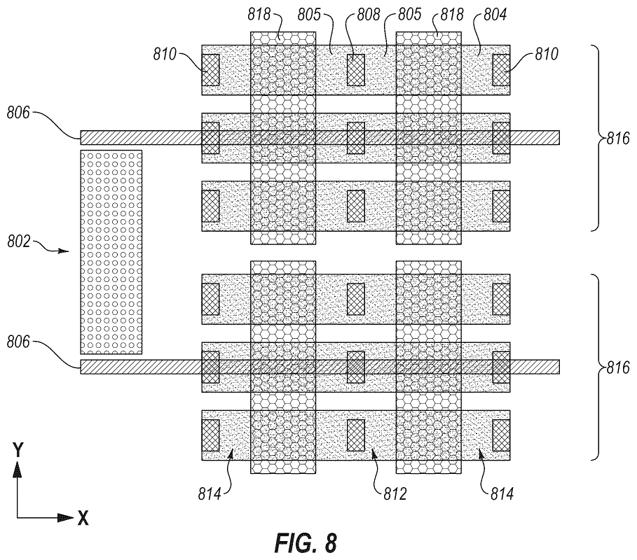

FIG. 8 illustrates a simplified, enlarged, top-down view of a block 802 and a group of BS devices 804 from a BS device array, such as the BS device array 110 (FIG. 1). The BS devices 804 illustrated in FIG. 8 are double-gated BS devices including two transistors 805 that share a source region 812. A block separation region 806 may extend longitudinally in the X-direction between blocks 802 of the associated microelectronic device. The BS devices 804 may be oriented and arranged, such that a long dimension of the BS devices 804 is substantially parallel with the block separation region 806 (e.g., such that the BS devices 804 extend longitudinally in the X-direction). In some embodiments, the dimension of the BS devices 804 are standardized, such that the length and width of the BS devices 804 are defined by industry standards. Thus, spacing or pitch of the BS devices 804 relative to one another may be defined by the industry standards.

Orienting the BS devices 804 to be parallel to the block separation region 806 (e.g., to respectively extend in the X-direction, and to be spaced apart from one another in the Y-direction) may facilitate positioning a greater number of BS devices 804 in association with the block 802 by reducing a lateral pitch in the Y-direction. For example, in the embodiment illustrated in FIG. 8 a group of six BS devices 804 are positioned within a horizontal span, in the Y-direction, of two of the blocks 802. The BS devices 804 are separated into two groups 816 of three BS devices 804. A first group 816 of the BS devices 804 is associated with the block 802 and another block horizontally neighboring a first lateral side (e.g., in the Y-direction) of the block 802. A second group 816 of the BS devices 804 is associated with the block 802 and a further block horizontally neighboring a second lateral side (e.g., in the Y-direction) of the block 802 opposing the first lateral side. A middle BS device 804 in each group 816 of three BS devices 804 horizontally overlaps (e.g., in the Y-direction) and is vertically offset from (e.g., in the Z-direction) the block separation region 806 separating the block 802 from a neighboring block.

Each of the BS devices 804 includes a global contact structure 808 in contact with the source region 812 the BS device 804, near a longitudinal center (e.g., in the X-direction) of the BS device 804. Each of the BS devices 804 includes two transistors 805 extending longitudinally from the source region 812 to drain regions 814 in contact with local contact structures 810 at opposing longitudinal ends of each of the BS devices 804. The BS devices 804 of each group 816 include BS gate electrodes 818 extending laterally in the Y-direction over the transistors 805 on each longitudinal side of the BS devices. The BS gate electrodes 818 are each associated with one of the blocks 802. The BS gate electrodes 818 are configured to induce a connection between the local contact structures 810 in contact with the associated transistors 805 and the global contact structure 808 in contact with the associated transistors 805 when activated. A first local contact structure 810 of the local contact structures 810 on each of the BS devices 804 may be associated with the block 802 (e.g., may be connected to components of the block 802 through one or more contact structures, conductive paths, or conductive vias). A second local contact structure 810 of the local contact structures 810 on each of the BS devices 804 may be associated with a neighboring block (e.g., a block positioned on one of the lateral sides of the block 802). Thus, the BS gate electrode 818 associated with the first local contact structure 810 may activate to induce a connection between the first local contact structure 810 and the global contact structure 808, operatively coupling the global contact structure 808 to the component of the block 802 coupled to the first local contact structure 810. In another instance, the BS gate electrode 818 associated with the second local contact structure 810 may activate to induce a connection between the second local contact structure 810 and the global contact structure 808, operatively coupling the global contact structure 808 to the component of the neighboring block coupled to the second local contact structure 810.

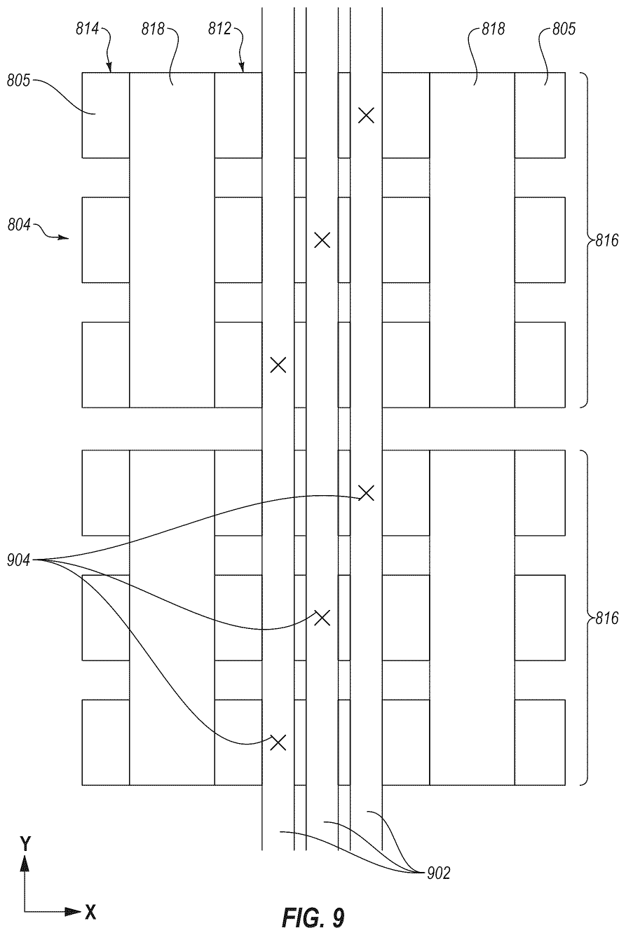

FIG. 9 is a simplified, enlarged, top-down view showing the BS devices 804 of FIG. 8. Global word lines 902 horizontally extend across (e.g., in the Y-direction) and are vertically offset from (e.g., in the Z-direction) the source regions 812 of the BS devices 804 in individual groups 816 of the BS devices 804. The number of global word lines 902 may match the number of BS devices 804 in each group 816 of BS devices 804. For example, in the embodiment illustrated in FIGS. 8 and 9, each group 816 of the BS devices 804 includes three BS devices 804. Therefore, three global word lines 902 horizontally extend across and are vertically offset from the source regions 812 of the BS devices 804.

The global word lines 902 are respectively connected to an individual BS device 804 through a contact point 904 coupled to the global contact structure 808 of the BS device 804. As illustrated in FIG. 9, each global word line 902 of the global word lines 902 is connected to a single BS device 804 of each group 816 of BS devices 804, such that a signal travelling along one global word line 902 is communicated to one pair of transistors 805 of a single BS device 804 in each group 816 of the BS devices 804.

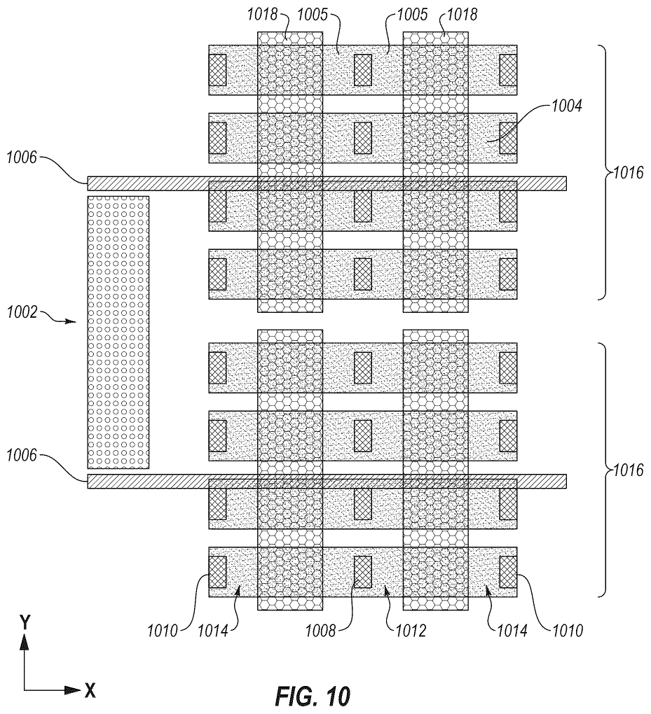

FIG. 10 illustrates a simplified, enlarged, top-down view of a block 1002 and a group of BS devices 1004 from a BS device array, such as the BS device array 110 (FIG. 1). A block separation region 1006 extends longitudinally in the X-direction between blocks 1002 of the associated microelectronic device. Similar to the block 802 of FIG. 8, the BS devices 1004 are oriented and arranged, such that a long dimension of the BS devices 1004 is substantially parallel with the block separation region 1006 (e.g., such that the BS devices 1004 extend longitudinally in the X-direction).

Orienting the BS devices 1004 parallel to the block separation region 1006 (e.g., to respectively extend in the X-direction, and to be spaced apart from one another in the Y-direction) may facilitate positioning a greater number of BS devices 1004 in association with a block 1002 by reducing a lateral pitch in the Y-direction. For example, in the embodiment illustrated in FIG. 10 a group of eight BS devices 1004 are positioned within a horizontal span, in the Y-direction, of two of the blocks 1002. The BS devices 1004 are separated into two groups 1016 of four BS devices 1004. A first group 1016 of the BS devices 1004 is associated with the block 1002 and another block horizontally neighboring a first lateral side of the block 1002. A second group 1016 of the BS devices 1004 is associated with the block 1002 and a further block horizontally neighboring a second lateral side of the block 1002 opposing the first lateral side. The block separation region 1006 may be positioned within a horizontal area between the middle two BS devices 1004 in each group 1016 of BS devices 1004.

Each of the BS devices 1004 includes a global contact structure 1008 in contact with a source region 1012 of the BS device 1004, near a longitudinal center of the BS devices 1004. Each of the BS devices 1004 include two transistors 805 extending longitudinally from the source region 812 to drain regions 1014 in contact with local contact structures 1010 at opposing longitudinal ends of each of the BS devices 1004 in drain regions 1014 of the BS devices 1004. The BS devices 1004 of each group 1016 include BS gate electrodes 1018 extend laterally in the Y-direction over the transistors 1005 on each longitudinal side of the BS devices 1004. The BS gate electrodes 1018 are each associated with one of the blocks 1002. The BS gate electrodes 1018 are configured to induce a connection between the local contact structures 1010 in contact with the associated transistors 1005 and the global contact structure 1008 in contact with the associated transistors 805 when activated. A first local contact structure 1010 of the local contact structures 1010 on each of the BS devices 1004 may be associated with the block 1002 (e.g., may be connected to components of the block 1002 through one or more contact structures, conductive paths, or conductive vias). A second local contact structure 1010 of the local contact structures 1010 on each of the BS devices 1004 may be associated with a neighboring block (e.g., a block positioned laterally neighboring, in the Y-direction, the block 1002). Thus, the BS gate electrode 1018 associated with the first local contact structure 1010 may activate to induce a connection between the first local contact structure 1010 and the global contact structure 1008, operatively coupling the global contact structure 1008 to the component of the block 1002 coupled to the first local contact structure 1010. In another instance, the BS gate electrode 1018 associated with the second local contact structure 1010 may activate to induce a connection between the second local contact structure 1010 and the global contact structure 1008, operatively coupling the global contact structure 1008 to the component of the neighboring block coupled to the second local contact structure 1010.

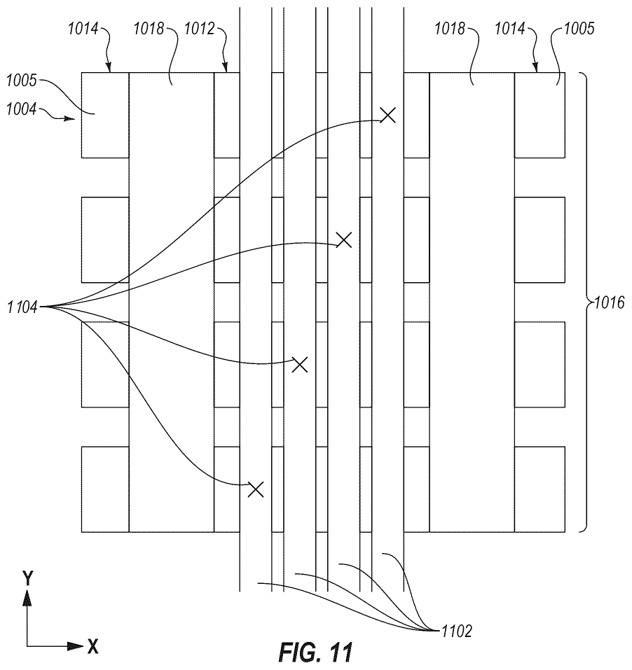

FIG. 11 is a simplified, enlarged, top-down view showing the BS devices 1004 of FIG. 10. Global word lines 1102 horizontally extend across (e.g., in the Y-direction) and are vertically offset from (e.g., in the Z-direction) the source regions 1012 of the BS devices 1004 in individual groups 1016 of the BS devices 1004. The number of global word lines 1102 may match the number of BS devices 1004 in each group 1016 of the BS devices 1004. For example, in the embodiment illustrated in FIGS. 10 and 11, each group 1016 of the BS devices 1004 includes four BS devices 1004. Therefore, four global word lines 1102 horizontally extend across and are vertically offset from the source region 1012 of the BS devices 1004.

The global word lines 1102 are respectively connected to an individual BS device 1004 through a contact point 1104 coupled to the global contact structure 1008 of the BS device 1004. As illustrated in FIG. 11, each global word line 1102 of the global word lines 1102 is connected to a single BS device 1004 of each group 1016 of BS devices 1004, such that a signal travelling along one global word line 1102 is communicated to one pair of transistors 805 of a single BS device 1004 in each group 1016 of BS devices 1004.

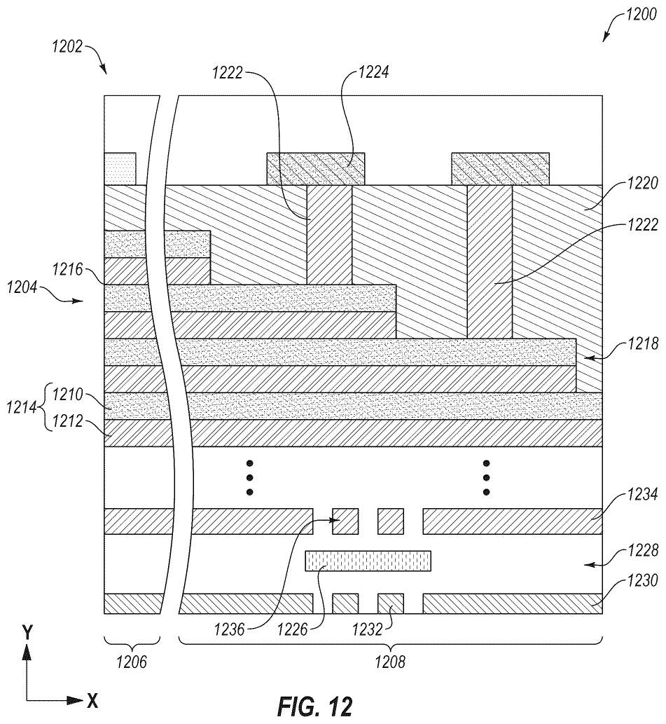

FIG. 12, illustrates a simplified, vertical cross-section of a memory device 1200 of a microelectronic device 1202 (e.g., microelectronic device 100). The memory device 1200 may include a stack structure 1204 arranged with a memory array region 1206 and a staircase region 1208. The stack structure 1204 includes vertically alternating conductive structures 1210 and insulative structures 1212 arranged in tiers 1214. The tiers 1214 extend to different longitudinal positions (in the X-direction), such that a portion of the conductive structures 1210 of each of the tiers 1214 extend beyond the tier 1214 that is vertically above the associated tier 1214. The extended portion forms a step 1216 in a staircase structure 1218 in the staircase region 1208.

The memory device 1200 may further include an isolation material 1220 on or over the stack structure 1204. The isolation material 1220 may be vertically disposed (e.g., in the Z-direction) over the stack structure 1204. The isolation material 1220 may substantially cover the staircase structures 1218 within the staircase region 1208 of the stack structure 1204, and may substantially surround side surfaces (e.g., sidewalls) of the conductive contact structures 1222 on the steps 1216 of the staircase structures 1218. The isolation material 1220 may exhibit a substantially planer upper vertical boundary, and a substantially non-planar lower vertical boundary complementary to the topography of at least the stack structure 1204 (including the staircase structures 1218 thereof) thereunder.

The isolation material 1220 may be formed of and include at least one dielectric material, such as one or more of at least one dielectric oxide material (e.g., one or more of SiOₓ, phosphosilicate glass, borosilicate glass, borophosphosilicate glass, fluorosilicate glass, AlOₓ, HfOₓ, NbOₓ, TiOₓ, ZrOₓ, TaOₓ, and MgOₓ), at least one dielectric nitride material (e.g., SiN_{y}), at least one dielectric oxynitride material (e.g., SiOₓN_{y}), and at least one dielectric carboxynitride material (e.g., SiOₓC_{z}N_{y}). The isolation material 1220 may include a substantially homogeneous distribution or a substantially heterogeneous distribution of the at least one dielectric material. In some embodiments, the isolation material 1220 exhibits a substantially homogeneous distribution of dielectric material. In further embodiments, the isolation material 1220 exhibits a substantially heterogeneous distribution of at least one dielectric material. The isolation material 1220 may, for example, be formed of and include a stack (e.g., laminate) of at least two different dielectric materials. In some embodiments, the isolation material 1220 is formed of and includes SiO₂.

Conductive contact structures 1222 extend vertically (e.g., in the Z-direction) through the isolation material 1220 providing vertical connections to the individual tiers 1214 by connecting to the tiers 1214 at the steps 1216 of the staircase structure 1218. While FIG. 12 illustrates a staircase structure 1218, other embodiments of a memory device may include a stack structure 1204 that does not include a staircase structure 1218 having steps 1216. In some such embodiments, conductive contact structures vertically extend through the stack structure 1204 to contact the conductive structures 1210 of the tiers 1214.

The memory device 1200 further includes conductive structures 1224 physically contacting at least some conductive contact structures 1222 of the memory device 1200. For example, the conductive structures 1224 may individually be sized, shaped, and positioned to physically contact and horizontally extend beyond horizontal boundaries of (e.g., in the X-direction, in the Y-direction) of a conductive contact stack structure 1204 located on a step 1216 of the stack structure 1204. In some such embodiments, each of the conductive structures 1224 individually physically contacts and horizontally extends past horizontal boundaries of one of the conductive contact structures 1222 located one of the steps 1216 of the stack structure 1204. In additional embodiments, at least some (e.g., all) of the conductive structures 1224 are omitted.

The conductive structures 1224 and conductive contact structures 1222, if present, may be formed of and include at least one electrically conductive material, such as one or more of a metal (e.g., W, Ti, Mo, Nb, V, Hf, Ta, Cr, Zr, Fe, Ru, Os, Co, Rh, Ir, Ni, Pd, Pt, Cu, Ag, Au, Al), an alloy (e.g., a Co-based alloy, an Fe-based alloy, an Ni-based alloy, an Fe-and Ni-based alloy, a Co-and Ni-based alloy, an Fe-and Co-based alloy, a Co-and Ni-and Fe-based alloy, an Al-based alloy, a Cu-based alloy, a Mg-based alloy, a Ti-based alloy, a steel, a low-carbon steel, a stainless steel), a conductive metal-containing material (e.g., a conductive metal nitride, a conductive metal silicide, a conductive metal carbide, a conductive metal oxide), a conductively doped semiconductor material (e.g., conductively doped Si, conductively doped Ge, conductively doped SiGe). The conductive structures 1224 and/or conductive contact structures 1222 may include substantially homogeneous distributions of the electrically conductive material or may include substantially heterogeneous distributions of the electrically conductive material. If the conductive structures 1224 exhibit substantially heterogeneous distributions of the electrically conductive material, amounts of the electrically conductive material may vary stepwise (e.g., change abruptly), or may vary continuously (e.g., change progressively, such as linearly, parabolically) throughout different portions of the conductive structures 1224. In some embodiments, the conductive structures 1224 each exhibit a substantially homogeneous distribution of electrically conductive material. In additional embodiments, one or more (e.g., each) of the conductive structures 1224 and/or the conductive contact structures 1222 exhibit a substantially heterogeneous distribution of at least one electrically conductive material.

Referring still to FIG. 12, BS devices 1226 (e.g., BS devices 114, 804, 1004) are arranged in a BS device array 1228 (e.g., the BS device array 110 (FIG. 1)). The BS device array 1228 may vertically underlie (e.g., in the Z-direction) and horizontally overlap (e.g., in the X-direction) the staircase region 1208, as illustrated in FIG. 12. In other embodiments, the BS device array 1228 may vertically overlie and horizontally overlap the staircase region 1208. Conductive routing 1230 is positioned to vertically neighbor the BS device array 1228. The conductive routing 1230 may include word lines 1232 configured to transmit or receive a signal to one or more of the BS devices 1226 in the BS device array 1228. Additional conductive routing structure 1234 is also positioned to vertically neighbor the BS device array 1228. The additional conductive routing structure 1234 may include additional conductive lines 1236 configured to connect other structures to one or more of the BS devices 1226 in the BS device array 1228. For example, the word lines 1232 of the conductive routing 1230 may be global word lines 1232 configured to receive or send signals to the associated transistors of the BS devices 1226 in the BS device array 1228; and the additional conductive lines 1236 of the additional conductive routing structure 1234 may be configured to operatively connect the associated transistors of the BS devices 1226 to other structures in the memory device 1200, such as conductive contact structures 1222, conductive structures 1224, and the conductive structures 1210 (e.g., serving as local word lines) in the tiers 1214.

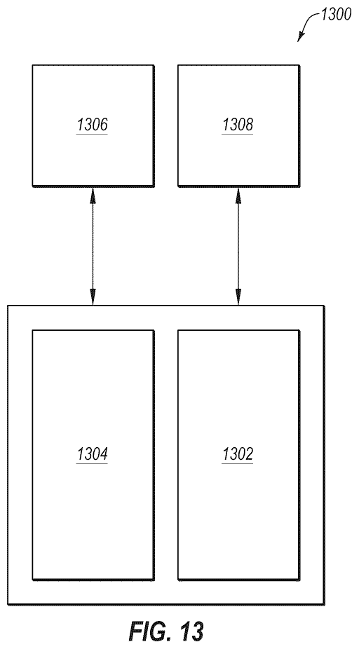

Microelectronic devices (e.g., the microelectronic devices 100, 1202) may be included in embodiments of electronic systems of the disclosure. For example, FIG. 13 is a block diagram of an electronic system 1300, in accordance with embodiments of the disclosure. The electronic system 1300 may comprise, for example, a computer or computer hardware component, a server or other networking hardware component, a cellular telephone, a digital camera, a personal digital assistant (PDA), portable media (e.g., music) player, a Wi-Fi or cellular-enabled tablet such as, for example, an iPAD® or SURFACE® tablet, an electronic book, or a navigation device. The electronic system 1300 includes at least one memory device 1302. The memory device 1302 may include, for example, an embodiment of a semiconductor device package including one or more of the microelectronic devices previously described herein (e.g., the microelectronic devices 100, 1202 previously described with reference to FIGS. 1 through 12).

The electronic system 1300 may further include at least one electronic signal processor device 1304 (often referred to as a “microprocessor”). The electronic signal processor device 1304 may, optionally, include an embodiment of one or more of a microelectronic device and a microelectronic device structure previously described herein (e.g., the microelectronic devices 100, 1202 previously described with reference to FIGS. 1 through 5F). The electronic system 1300 may further include one or more input devices 1306 for inputting information into the electronic system 1300 by a user, such as, for example, a mouse or other pointing device, a keyboard, a touchpad, a button, or a control panel. The electronic system 1300 may further include one or more output devices 1308 for outputting information (e.g., visual or audio output) to a user such as, for example, a monitor, a display, a printer, an audio output jack, or a speaker. In some embodiments, the input device 1306 and the output device 1308 may comprise a single touchscreen device that can be used both to input information to the electronic system 1300 and to output visual information to a user. The input device 1306 and the output device 1308 may communicate electrically (e.g., be operably connected) with one or more of the memory device 1302 and the electronic signal processor device 1304.

Thus, embodiments of the disclosure include a microelectronic device. The microelectronic device includes blocks. Each block includes a vertically alternating sequence of conductive structures and insulative structures arranged in tiers. The microelectronic device further includes an array of block select (BS) devices vertically offset from the blocks. The array includes a first row of BS devices comprising double-gated BS devices, the double-gated BS devices respectively having two transistors sharing a source region. The array further includes a second row of BS devices comprising single-gated BS devices respectively having only one transistor. The array also includes a global word line structure coupled to a first source region of one of the double-gated BS devices of the first row of BS devices and a second source region of one of the single-gated BS devices of the second row of BS devices.

Another embodiment of the disclosure includes an electronic system. The electronic system includes an input device, an output device, a processor device operably coupled to the input device and the output device, and a memory device operably coupled to the processor device. The memory device includes a microelectronic device. The microelectronic device includes blocks horizontally extending in parallel in a first direction and horizontally separated from one another in a second direction orthogonal to the first direction, the blocks respectively comprising a vertically alternating sequence of conductive structures and insulative structures arranged in tiers. The microelectronic device further includes at least one BS device vertically offset from and within a horizontal area of one of the blocks, the at least one BS device horizontally extending in parallel with the blocks in the first direction.

Other embodiments of the disclosure include a memory device. The memory device includes two planes. The two planes respectively include two blocks. The two planes further include an array of BS devices comprising a row of double-gated BS devices, the double-gated BS devices of the row respectively include two transistors sharing a source region. The memory device further includes a space defined between the two planes, one of the two planes comprising an end row of BS devices in the array of BS devices, the end row of BS devices positioned proximate to the space and comprising single-gated BS devices respectively including only one transistor.

The BS device arrangements of the embodiments of the disclosure facilitate larger numbers of transistors being positioned in a unit area of a microelectronic device as compared to conventional configurations including conventional arrangements of BS devices. Increasing the number of control logic devices in a unit of die area may facilitate further increases in memory array density. Increased memory array density may facilitate reducing the size of a memory device and/or associated electronic device or system. Increased memory array density may also facilitate increases in memory and/or processing power in an electronic device or system without increasing the size of the associated electronic device or system.

The embodiments of the disclosure described above and illustrated in the accompanying drawing figures do not limit the scope of the invention, since these embodiments are merely examples of embodiments of the invention, which is defined by the appended claims and their legal equivalents. Any equivalent embodiments are intended to be within the scope of this disclosure. Indeed, various modifications of the present disclosure, in addition to those shown and described herein, such as alternative useful combinations of the elements described, may become apparent to those skilled in the art from the description. Such modifications and embodiments are also intended to fall within the scope of the appended claims and their legal equivalents.

What is claimed is:

1. A microelectronic device comprising:
blocks each comprising a vertically alternating sequence of conductive structures and insulative structures arranged in tiers;
an array of block select (BS) devices vertically offset from the blocks and comprising:
a first row of BS devices comprising double-gated BS devices, the double-gated BS devices respectively having two transistors sharing a source region;
a second row of BS devices comprising single-gated BS devices respectively having only one transistor; and
a global word line structure coupled to a first source region of one of the double-gated BS devices of the first row of BS devices and a second source region of one of the single-gated BS devices of the second row of BS devices.

2. The microelectronic device of claim 1, wherein the array of BS devices further comprising a third row of BS devices comprising double-gated BS devices, the second row of BS devices positioned between the first row of BS devices and the third row of BS devices.

3. The microelectronic device of claim 2, wherein:
the double-gated BS devices of the first row of BS devices respectively include a first drain region positioned horizontally proximate to the second row of BS devices;
the second source region of the single-gated BS devices in the second row of BS devices are respectively positioned horizontally proximate to the first row of BS devices;
the single-gated BS devices of the second row of BS devices further respectively include a second drain region positioned horizontally proximate to the third row of BS devices; and
a distance between the first row of BS devices and the second row of BS devices is greater than a distance between the second row of BS devices and the third row of BS devices.

4. The microelectronic device of claim 1, further comprising a block separation region between the blocks.

5. The microelectronic device of claim 4, wherein the first row of BS devices is positioned such that the first source region of the double-gated BS devices horizontally overlaps the block separation region.

6. The microelectronic device of claim 4, wherein the second row of BS devices is positioned such that the block separation region is horizontally between the second source region of respective ones of the single-gated BS devices and a drain region of respective ones of the single-gated BS devices.

7. The microelectronic device of claim 1, wherein:
the double-gated BS devices of the first row of BS devices each comprise a first local contact structure and a second local contact structure;
the single-gated BS devices of the second row of BS devices each comprise a third local contact structure; and
the first local contact structure of each of the double-gated BS devices in the first row of BS devices is operatively connected to a same block of the blocks as the third local contact structure of some respective ones of the single-gated BS devices of the second row of BS devices.

8. The microelectronic device of claim 1, wherein the array of BS devices includes at least five rows of transistors within a horizontal span of three of the blocks.

9. An electronic system, comprising:
an input device;
an output device;
a processor device operably coupled to the input device and the output device; and
a memory device operably coupled to the processor device; the memory device comprising a microelectronic device comprising:
blocks horizontally extending in parallel in a first direction and horizontally separated from one another in a second direction orthogonal to the first direction, the blocks respectively comprising a vertically alternating sequence of conductive structures and insulative structures arranged in tiers; and
at least one BS device vertically offset from and within a horizontal area of one of the blocks, the at least one BS device horizontally extending in parallel with the blocks in the first direction.

10. The electronic system of claim 9, further comprising a global word line coupled to a source region of the BS device and horizontally extending in the second direction.

11. The electronic system of claim 9, wherein the at least one BS device comprises multiple BS devices arranged in groups of BS devices.

12. The electronic system of claim 11, wherein each of the groups of BS devices respectively comprises at least three BS devices.

13. The electronic system of claim 11, further comprising global word lines horizontally overlapping the groups of BS devices in the first direction and horizontally extending in parallel in the second direction.

14. The electronic system of claim 13, wherein a quantity of the global word lines is equal to a quantity of the BS devices in one of the groups of BS devices.

15. A memory device comprising:
two planes respectively comprising:
two blocks; and
an array of BS devices comprising a row of double-gated BS devices, the double-gated BS devices of the row respectively including two transistors sharing a source region; and
a space defined between the two planes, one of the two planes comprising an end row of BS devices in the array of BS devices, the end row of BS devices positioned proximate to the space and comprising single-gated BS devices respectively including only one transistor.

16. The memory device of claim 15, wherein one or more BS devices of the array of BS devices comprise dummy transistors.

17. The memory device of claim 16, wherein the dummy transistors comprise a portion of one row of the BS devices in the array of BS devices.

18. The memory device of claim 16, wherein the dummy transistors comprise transistors proximate one lateral side of the double-gated BS devices of the row of double-gated BS devices.

19. The memory device of claim 16, wherein the BS devices in the end row of BS devices extend into the space defined between the two planes by an overlap distance.

20. The memory device of claim 19, wherein the overlap distance is less than about 40 μm.
